(19) United States
(12) Patent Application Publication
(10) Pub. No.: US 2025/0022835 A1
(43) Pub. Date: Jan. 16, 2025

(54) SEMICONDUCTOR MODULE

(71) Applicant: FUJI ELECTRIC CO., LTD., Kawasaki-shi (JP)

(72) Inventor: Hideo AMI, Matsumoto-city (JP)

(73) Assignee: FUJI ELECTRIC CO., LTD., Kawasaki-shi (JP)

(21) Appl. No.: 18/899,692

(22) Filed: Sep. 27, 2024

Related U.S. Application Data
(63) Continuation of application No. PCT/JP2023/032066, filed on Sep. 1, 2023.

(30) Foreign Application Priority Data
Oct. 31, 2022 (JP) 2022-174506

(51) Int. Cl. H01L 23/00; H01L 23/057; H01L 23/498; H01L 23/538; H01L 25/07

(52) U.S. Cl. CPC H01L 24/49; H01L 23/057; H01L 23/49811; H01L 23/5385; H01L 24/48; H01L 25/072; H01L 2224/48137; H01L 2224/48225; H01L 2224/49112

(57) ABSTRACT

A semiconductor module includes at least one substrate and semiconductor switching elements. The substrate includes a first electrode pattern, a second electrode pattern, and a third electrode pattern, in which the first electrode pattern is positioned between the second electrode pattern and the third electrode pattern in plan view. Each semiconductor switching element has a first surface to be joined to the first electrode pattern, and a second surface facing in an opposite direction to the first surface. On the second surface, a control electrode, a control line to be connected to the control electrode, and a main electrode including regions divided by the control line are provided. Each of the regions is electrically connected to the second electrode pattern via a first wire and is electrically connected to the third electrode pattern via a second wire. The second electrode pattern is a pattern for a principal current. The third electrode pattern is used as an auxiliary pattern for control.

### CROSS REFERENCE TO RELATED APPLICATIONS

This Application is a Continuation Application of PCT Application No. PCT/JP2023/032066, filed on Sep. 1, 2023, and is based on and claims priority from Japanese Patent Application No. 2022-174506, filed on Oct. 31, 2022, the entire contents of each of which are incorporated herein by reference.

### BACKGROUND OF THE INVENTION

### Field of the Invention

The present disclosure relates to semiconductor modules.

### Description of Related Art

Some types of semiconductor modules, such as power semiconductor modules, have configurations in which semiconductor switching elements are connected in parallel.

For example, a semiconductor module described in Patent Document 1 (WO 2019/044748) includes an insulating substrate on which semiconductor switching elements are mounted. On the insulating substrate, a drain pattern, a source pattern, a source control pattern, and a gate control pattern are provided to the same semiconductor switching elements. A drain pad of each of the semiconductor switching elements is joined to the drain pattern. A source pad of each of the semiconductor switching elements is electrically connected to the source pattern by a wire. The source pad of each of the semiconductor switching elements is electrically connected to the source control pattern with a wire. A gate pad of each of the semiconductor switching elements is electrically connected to the gate control pattern by a wire.

The configuration described in Patent Document 1 has a problem in that the wires for electrically connecting the source pads to the source control pattern are joined at unevenly distributed positions in the plane of the source pad, so that imbalance of a current in the source pad occurs and switching characteristics are consequently deteriorated.

### SUMMARY

In view of the above circumstances, an aspect of the present disclosure has an object of increasing the switching characteristics of a semiconductor module.

In order to solve the above problem, a semiconductor module according to a preferred aspect of the present disclosure includes: at least one substrate that has a first electrode pattern, a second electrode pattern, and a third electrode pattern, the first electrode pattern being positioned between the second electrode pattern and the third electrode pattern in plan view; and a plurality of semiconductor switching elements that each have a first surface to be joined to the first electrode pattern, and a second surface facing in an opposite direction to the first surface, in which a control electrode, a control line to be connected to the control electrode, and a main electrode having a plurality of regions divided by the control line are provided on the second surface, each of the regions is electrically connected to the second electrode pattern via a first wire, and is electrically connected to the third electrode pattern via a second wire, the second electrode pattern is a pattern for a principal current, and the third electrode pattern is used as an auxiliary pattern for control.

### BRIEF DESCRIPTION OF THE DRAWINGS

FIG. 1 is a sectional view of a semiconductor module according to an embodiment.

FIG. 2 is a plan view of the semiconductor module according to the embodiment, with a part omitted.

FIG. 3 is a circuit diagram of an upper arm of the semiconductor module.

FIG. 4 is a circuit diagram of an upper arm of a semiconductor module having a configuration in which an auxiliary control terminal is connected to principal current paths.

FIG. 5 is a side view for explaining a semiconductor switching elements and semiconductor elements on each of substrates for the upper arm.

FIG. 6 is a plan view illustrating a configuration of each of the substrates for the upper arm.

FIG. 7 is a plan view illustrating a configuration of each of substrates for a lower arm.

FIG. 8 is a plan view illustrating a configuration example of control terminals.

FIG. 9 is a plan view illustrating a configuration of a substrate for an upper arm according to a first modification.

FIG. 10 is a plan view illustrating a configuration of a substrate for a lower arm according to the first modification.

### MODES FOR CARRYING OUT THE INVENTION

Preferred embodiment according to the present disclosure will be explained below with reference to the accompanying drawings. The dimensions and scales of respective parts in the drawings are different from those of actual products as appropriate and some parts are schematically illustrated to facilitate understanding. The scope of the present disclosure is not limited to the embodiments unless otherwise it is stated in the following explanations that the present disclosure is specifically limited.

### 1. Embodiment

1-1. Overall configuration of semiconductor module

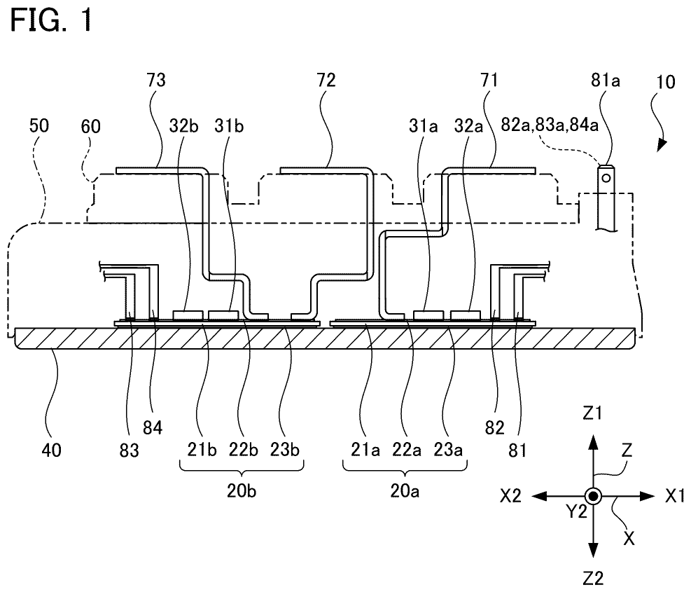

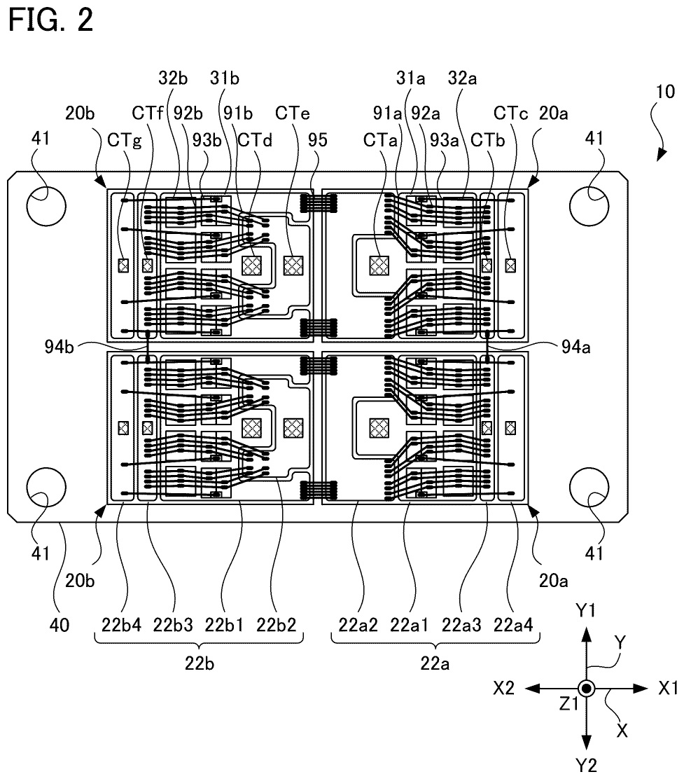

FIG. 1 is a sectional view of a semiconductor module 10 according to an embodiment. FIG. 2 is a plan view of the semiconductor module 10 according to the embodiment, with a part omitted. In FIG. 1, for the sake of simplicity, illustrations of wires 91a, 91b, 92a, 92b, 93a, 93b, 94a, 94b, and 95 described later are omitted and outer shapes of a housing 50 and a lid 60 described later are indicated by dash-double dot lines. In FIG. 2, illustrations of the housing 50, the lid 60, main terminals 71, 72, and 73, and control terminals 81, 82, 83, and 84 are omitted for explanatory convenience.

The semiconductor module 10 is a power module, such as an IGBT (Insulated Gate Bipolar Transistor) module. The semiconductor module 10 is used, for example, for power control in an apparatus used industrially, such as an inverter or a rectifier, which is mounted in a device, such as a rail vehicle, an automobile, or a household electrical appliance.

As illustrated in FIGS. 1 and 2, the semiconductor module 10 includes two substrates 20a, two substrates 20b, eight semiconductor switching elements 31a, eight semiconductor switching elements 31b, eight semiconductor elements 32a, eight semiconductor elements 32b, a base 40, the housing 50, the lid 60, the main terminals 71, 72, and 73, the control terminals 81, 82, 83, and 84, and the wires 91a, 91b, 92a, 92b, 93a, 93b, 94a, 94b, and 95.

Each of the control terminals 82 and 84 is an example of a “first control terminal.” Each of the control terminals 81 and 83 is an example of a “second control terminal.” Each of the wires 91a and 91b is an example of a “first wire.” Each of the wires 92a and 92b is an example of a “second wire.” Each of the wires 93a and 93b is an example of a “third wire.” Each of the wires 94a and 94b is an example of a “fourth wire.”

The eight semiconductor switching elements 31a and the eight semiconductor elements 32a are mounted on the two substrates 20a to be distributed thereon, and are electrically connected in parallel by the wires 91a, 92a, 93a, and 94a to constitute an upper arm of an inverter circuit. The eight semiconductor switching elements 31b and the eight semiconductor elements 32b are mounted on the two substrates 20b to be distributed thereon, and are electrically connected in parallel by the wires 91b, 92b, 93b, and 94b to constitute a lower arm of the inverter circuit. The upper arm and the lower arm are electrically connected to each other by the wires 95.

Outlines of components of the semiconductor module 10 are first explained sequentially below with reference to FIGS. 1 and 2. In the following explanations, an X-axis, a Y-axis, and a Z-axis orthogonal to one another are properly used for explanatory convenience. The Z-axis is an axis parallel to the direction of the thickness or height of the semiconductor module 10. Hereinafter, one direction along the X-axis is the X1 direction. The direction opposite to the X1 direction is an X2 direction. One direction along the Y-axis is the Y1 direction and the direction opposite to the Y1 direction is the Y2 direction. One direction along the Z-axis is the Z1 direction and the direction opposite to the Z1 direction is the Z2 direction. The relationships between these directions and the vertical direction is not limited to a specific one and any relationship may be employed. Hereinafter, viewing in the direction along the Z-axis is also referred to as “plan view.”

Each of the two substrates 20a is a substrate housed in the housing 50 and having four semiconductor switching elements 31a and four semiconductor elements 32a mounted thereon. Similarly, each of the two substrates 20b is a substrate housed in the housing 50 and having four semiconductor switching elements 31b and four semiconductor elements 32b mounted thereon.

In an example illustrated in FIGS. 1 and 2, the two substrates 20a are arranged in the direction along the Y-axis. The two substrates 20b are arranged in the direction along the Y-axis at positions in the X2 direction with respect to the two substrates 20a. One substrate 20a out of the two substrates 20a is arranged in the X1 direction with respect to one substrate 20b out of the two substrates 20b. The other substrate 20a is arranged in the X1 direction with respect to the other substrate 20b.

Each of the substrates 20a and the substrates 20b is, for example, a multilayer substrate, such as a DCB (Direct Copper Bonding) substrate or a DBA (Direct Bonded Aluminum) substrate. Specifically, each of the substrates 20a includes an insulating plate 21a, a wiring layer 22a, and a radiating layer 23a as illustrated in FIG. 1. Similarly, each of the substrates 20b includes an insulating plate 21b, a wiring layer 22b, and a radiating layer 23b.

Each of the insulating plate 21a and the insulating plate 21b is an insulating plate and is constituted of, for example, ceramics such as aluminum nitride, aluminum oxide, or silicon nitride. The wiring layer 22a is provided on one of the surfaces of the insulating plate 21a, and the radiating layer 23a is provided on the other surface. Similarly, the wiring layer 22b is provided on one of surfaces of the insulating plate 21b and the radiating layer 23b is provided on the other surface. Each of the wiring layers 22a and 22b and the radiating layers 23a and 23b is constituted of a metal, such as copper or aluminum.

The wiring layer 22a is a conductive layer on which the semiconductor switching elements 31a and the semiconductor elements 32a are to be mounted. The main terminal 71 and the control terminals 81 and 82 are joined to the wiring layer 22a with a conductive joining material such as solder. The radiating layer 23a is a thermally conductive layer for releasing heat from the semiconductor switching elements 31a and the semiconductor elements 32a to the base 40 and is joined to the base 40 with a conductive joining material such as solder.

Similarly, the wiring layer 22b is a conductive layer on which the semiconductor switching elements 31b and the semiconductor elements 32b are to be mounted. The main terminals 72 and 73 and the control terminals 83 and 84 are joined to the wiring layer 22b with a conductive joining material such as solder. The radiating layer 23b is a thermally conductive layer for releasing heat from the semiconductor switching elements 31b and the semiconductor elements 32b to the base 40 and is joined to the base 40 with a conductive joining material such as solder.

In detail, the wiring layer 22a has electrode patterns 22a1, 22a2, 22a3, and 22a4 that are arranged spaced apart from one another, as illustrated in FIG. 2. Similarly, the wiring layer 22b has electrode patterns 22b1, 22b2, 22b3, and 22b4 that are arranged spaced apart from one another.

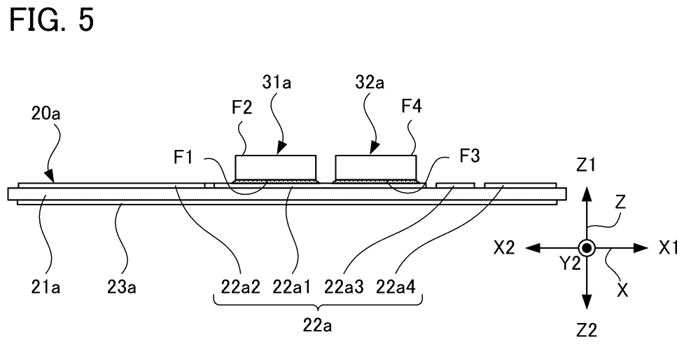

Each of the electrode pattern 22al and the electrode pattern 22b1 is one example of a “first electrode pattern.” Each of the electrode pattern 22a2 and the electrode pattern 22b2 is one example of a “second electrode pattern.” Each of the electrode patterns 22a1, 22b1, 22a2, and 22b2 is a pattern for a principal current. The principal current is the maximum current flowing in the semiconductor switching elements 31a or the semiconductor switching elements 31b and is, for example, a current flowing between an emitter electrode and a collector electrode or a current flowing between a source electrode and a drain electrode. Each of the electrode pattern 22a3 and the electrode pattern 22b3 is one example of a “third electrode pattern” and is used as an auxiliary pattern for control. Each of the electrode pattern 22a4 and the electrode pattern 22b4 is one example of a “fourth electrode pattern” and is used as a main pattern for control. Details of these electrode patterns will be described later with reference to FIGS. 5 to 7.

The back surface of each of the semiconductor switching elements 31a and the semiconductor elements 32a is joined to the electrode pattern 22al of the wiring layer 22a with a conductive joining material such as solder. Similarly, the back surface of each of the semiconductor switching elements 31b and the semiconductor elements 32b is joined to the electrode pattern 22b1 of the wiring layer 22b with a conductive joining material such as solder.

Although illustrations of the main terminals 71, 72, and 73 and the control terminals 81, 82, 83, and 84 are omitted in FIG. 2, regions CTa, CTb, CTc, CTd, CTe, CTf, and CTg are shown which is used to connect these terminals to the wiring layers 22a and 22b with conductive joining materials, such as solder.

The region CTa is used to join the main terminal 71 and is provided on the electrode pattern 22a1 of the wiring layer 22a. The region CTb is used to join the control terminal 82 and is provided on the electrode pattern 22a3 of the wiring layer 22a. The region CTc is used to join the control terminal 81 and is provided on the electrode pattern 22a4 of the wiring layer 22a. The region CTd is used to join the main terminal 73 and is provided on the electrode pattern 22b1 of the wiring layer 22b. The region CTe is used to join the main terminal 72 and is provided on the electrode pattern 22b2 of the wiring layer 22b. The region CTf is used to join the control terminal 84 and is provided on the electrode pattern 22b3 of the wiring layer 22b. The region CTg is used to join the control terminal 83 and is provided on the electrode pattern 22b4 of the wiring layer 22b.

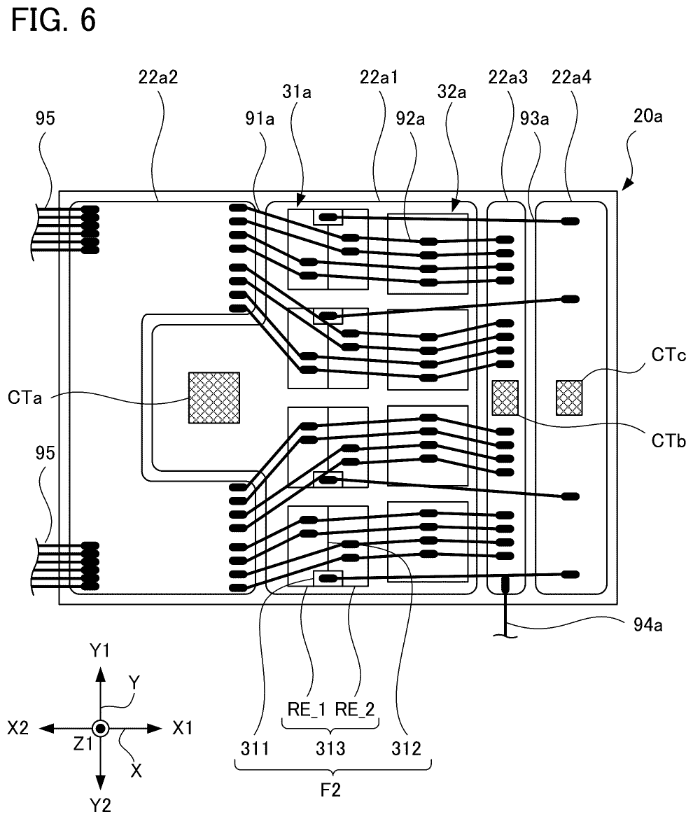

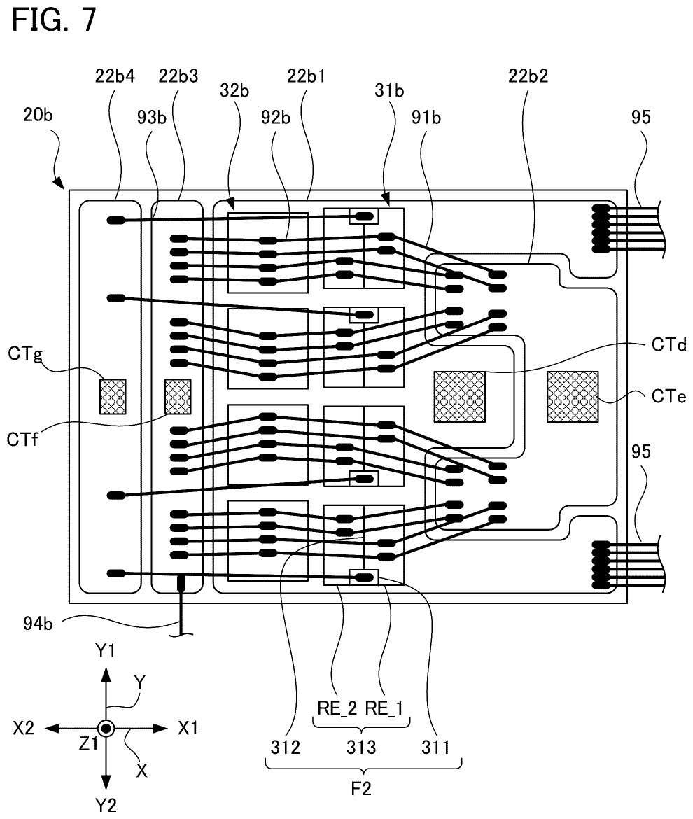

Each of the semiconductor switching elements 31a and the semiconductor switching elements 31b is a switching element, such as an IGBT (Insulated Gate Bipolar Transistor) or a power MOSFET (metal-oxide-semiconductor field-effect transistor). An input electrode is provided on the back surface (a first surface) of each of the semiconductor switching elements 31a and the semiconductor switching elements 31b. The input electrode is a drain electrode or a collector electrode. In addition, an output electrode (a main electrode) and a control electrode are provided on the front surface (a second surface) of each of the semiconductor switching elements 31a and the semiconductor switching elements 31b. The output electrode is a source electrode or an emitter electrode. The control electrode is a gate electrode. Details of the front surface will be described with reference to FIGS. 6 and 7.

Each of the semiconductor elements 32a and the semiconductor elements 32b is an FWD (Freewheeling Diode). An output electrode is provided on the back surface (a third surface) of each of the semiconductor elements 32a and the semiconductor elements 32b. The output electrode is a cathode electrode. In addition, an input electrode is provided on the front surface (a fourth surface) of each of the semiconductor elements 32a and 32b. The input electrode is an anode electrode.

The base 40 is a radiating plate and constitutes a bottom plate of the semiconductor module 10. The two substrates 20a and the two substrates 20b described above are joined to the upper surface of the base 40. A radiating member (not illustrated), such as a radiating fin, may be arranged on the lower surface of the base 40. The base 40 is, for example, a metallic plate constituted of copper, a copper alloy, aluminum, or an aluminum alloy. The base 40 is thermally conductive and radiates heat from the semiconductor switching elements 31a and 31b and the semiconductor elements 32a and 32b. The base 40 is conductive and may be, for example, electrically connected to a reference potential such as a ground potential.

In the example illustrated in FIG. 2, the thickness direction of the base 40 is the direction along the Z-axis. When viewed in the direction along the Z-axis, the base 40 has a shape including one pair of long sides extending in the direction along the X-axis and one pair of short sides extending in the direction along the Y-axis. An attachment hole 41 is provided on the base 40 near each corner. The attachment holes 41 are, for example, through-holes to be used to screw a radiating member (not illustrated), such as a radiating fin onto the base 40. The shape of the base 40 in plan view is not limited to that in the example illustrated in FIG. 2 and may be any shape. The attachment holes 41 are provided as required and may be omitted.

The housing 50 is a frame-shaped member for zoning an interior space in which to house the semiconductor switching elements 31a and 31b and the semiconductor elements 32a and 32b. The housing 50 is insulative and is constituted of a resin, such as PPS (polyphenylene sulfide) or PBT (polybutylene terephthalate). The housing 50 is obtained by injection molding or the like. The housing 50 may be constituted integrally with the main terminals 71, 72, and 73 and the control terminals 81, 82, 83, and 84 by insert molding or the like. The resin may contain inorganic fiber, such as glass fiber, or it may contain inorganic fillers, such as alumina or silica, in view of improvement in mechanical strength or thermal conductivity of the housing 50.

A sealing resin may be filled in the housing 50. The sealing resin is a potting material that coats the semiconductor switching elements 31a and 31b and the semiconductor elements 32a and 32b. The sealing resin is constituted of a thermosetting resin, such as an epoxy resin or a silicone resin. It is preferable that inorganic fillers, such as silica or alumina, be contained in the sealing resin in view of enhancement of thermal conductivity. The sealing resin may be gel.

Although not illustrated in the drawings, the internal space of the housing 50 is open in each of the Z1 direction and the Z2 direction. The base 40 is joined to the housing 50 with an adhesive or the like to close the opening of the housing 50 facing in the Z2 direction. The lid 60 is joined to the housing 50 with an adhesive or the like to close the opening of the housing 50 facing in the Z1 direction.

The lid 60 is a member that closes the opening of the housing 50 facing in the Z1 direction. The lid 60 is constituted of a resin material, such as PPS (polyphenylene Sslfide) or PBT (polybutylene terephthalate), similarly to the housing 50. In the example illustrated in FIG. 1, the lid 60 has a function to support portions of the main terminals 71, 72, and 73. The lid 60 may be a housing for screwing each of the main terminals 71, 72, and 73 to a busbar (not illustrated).

Each of the main terminals 71, 72, and 73 is a terminal for connecting a busbar (not illustrated) to the semiconductor module 10 and has a portion exposed outside the semiconductor module 10. In the example illustrated in FIG. 1, the main terminals 71, 72, and 73 penetrate through the lid 60 and a portion of each of the main terminals 71, 72, and 73 is exposed outside the semiconductor module 10.

The main terminal 71 is a high-potential terminal and is joined to the region CTa. The main terminal 72 is a low-potential terminal and is joined to the CTe described above. The main terminal 73 is a terminal for outputting and is joined to the region CTd described above. Each of the main terminals 71, 72, and 73 is constituted of a metal, such as copper, a copper alloy, aluminum, an aluminum alloy, or an iron alloy. Each main terminal 71, 72, and 73 is obtained by folding of a metallic plate, or the like.

Each of the control terminals 81 and 82 is a terminal for connecting a control circuit (not illustrated) that controls the operations of the semiconductor switching elements 31a to the semiconductor module 10. The control circuit is installed outer to the semiconductor module 10. The control terminal 81 has a terminal part 81a exposed outside the semiconductor module 10. A signal for controlling the operations of the semiconductor switching elements 31a is supplied to the control terminal 81 from the control circuit. The control terminal 82 has a terminal part 82a exposed outside the semiconductor module 10. A constant potential being a reference for the signal is supplied to the control terminal 82 from the control circuit.

Similarly, each of the control terminals 83 and 84 is a terminal for connecting a control circuit (not illustrated) that controls the operations of the semiconductor switching elements 31b to the semiconductor module 10. The control circuit is installed outside the semiconductor module 10. The control terminal 83 has a terminal part 83a exposed outside the semiconductor module 10. A signal for controlling the operations of the semiconductor switching elements 31b is supplied to the control terminal 83 from the control circuit. The control terminal 84 has a terminal part 84a exposed outside the semiconductor module 10. A constant potential being a reference for the signal is supplied to the control terminal 84 from the control circuit.

Each of the control terminals 81, 82, 83, and 84 is constituted of a metal, such as copper, a copper alloy, aluminum, an aluminum alloy, or an iron alloy. Each control terminal 81, 82, 83 is obtained by folding a metal plate, similarly to the main terminals 71, 72, and 73.

Each of the wires 91a, 91b, 92a, 92b, 93a, 93b, 94a, 94b, and 95 is a conductive wire or wire group constituted of at least one bonding wire.

The wire 91a is joined to each of the electrode pattern 22a2 of the wiring layer 22a and the output electrode of the semiconductor switching element 31a. With this joining, the electrode pattern 22a2 and the output electrode of the semiconductor switching element 31a are electrically connected to each other via the wire 91a. Similarly, the wire 91b is joined to each of the electrode pattern 22b2 of the wiring layer 22b and the output electrode of the semiconductor switching element 31b. With this joining, the electrode pattern 22b2 and the output electrode of the semiconductor switching element 31b are electrically connected to each other via the wire 91b.

The wire 92a is joined to each of the output electrode of the semiconductor switching element 31a, the output electrode of the semiconductor element 32a, and the electrode pattern 22a3 of the wiring layer 22a. With this joining, the output electrode of the semiconductor switching element 31a, the output electrode of the semiconductor element 32a, and the electrode pattern 22a3 are electrically connected to one another via the wire 92a. Similarly, the wire 92b is joined to each of the output electrode of the semiconductor switching element 31b, the output electrode of the semiconductor element 32b, and the electrode pattern 22b3 of the wiring layer 22b. With this joining, the output electrode of the semiconductor switching element 31b, the output electrode of the semiconductor element 32b, and the electrode pattern 22b3 are electrically connected to one another via the wire 92b.

The wire 93a is joined to each of the electrode pattern 22a4 of the wiring layer 22a and the control electrode of the semiconductor switching element 31a. With this joining, the electrode pattern 22a4 and the control electrode of the semiconductor switching element 31a are electrically connected to each other via the wire 93a. Similarly, the wire 93b is joined to each of the electrode pattern 22b4 of the wiring layer 22b and the control electrode of the semiconductor switching element 31b. With this joining, the electrode pattern 22b4 and the control electrode of the semiconductor switching element 31b are electrically connected to each other via the wire 93b.

The wire 94a is joined to the electrode pattern 22a4 of each of the two substrates 20a. With this joining, the electrode patterns 22a4 of the two substrates 20a are electrically connected to each other via the wire 94a. Similarly, the wire 94b is joined to the electrode pattern 22b4 of each of the two substrates 20b. With this joining, the electrode patterns 22b4 of the two substrates 20b are electrically connected to each other via the wire 94b.

The wires 95 are joined to each of the electrode pattern 22a2 and the electrode pattern 22b1 in the substrate 20a and the substrate 20b adjacent in the direction along the X-axis. With this joining, the electrode pattern 22a2 and the electrode pattern 22b1 in the substrate 20a and a substrate 20b adjacent in the direction along the X-axis are electrically connected to each other via the wires 95.

As described above, each of the electrode patterns 22a2 is electrically connected to the output electrodes of the semiconductor switching elements 31a. In contrast thereto, each of the electrode patterns 22b1 is electrically connected to the input electrodes of the semiconductor switching elements 31b. Therefore, in the substrate 20a and the substrate 20b adjacent in the direction along the X-axis, the semiconductor switching elements 31a and the semiconductor switching element 31b are electrically connected in series with each other.

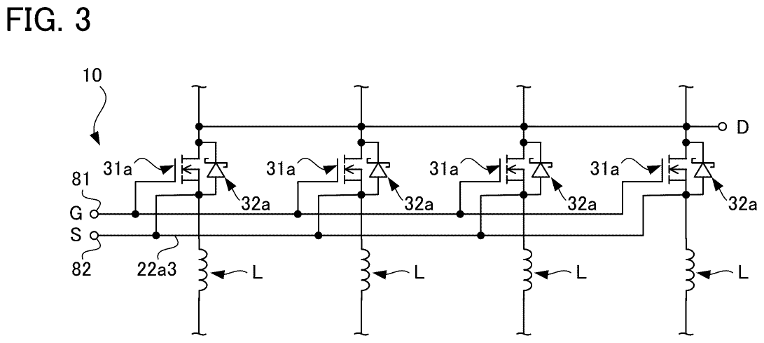

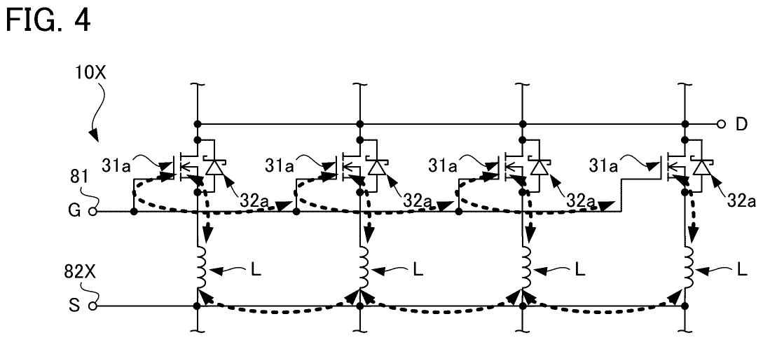

In the above semiconductor module 10, the electrode patterns 22a3 to be used as auxiliary patterns for control are separate members from the electrode patterns 22a2 in the upper arm. As a result, the control terminal 82 is electrically connected to the output electrodes of the semiconductor switching elements 31a without passing a principal current path. A current path for controlling driving of each of the semiconductor switching elements 31a is less likely to be affected by current variation in the principal current path and switching characteristics of the semiconductor switching elements 31a can therefore be improved. Similarly, since the electrode patterns 22b3 to be used as auxiliary patterns for control are separate members from the electrode patterns 22b2 in the lower arm, the control terminal 84 is electrically connected to the output electrodes of the semiconductor switching elements 31b without via a principal current path. A current path for controlling driving of each of the semiconductor switching elements 31b is less likely to be affected by current variations in the principal current path and switching characteristics of the semiconductor switching elements 31b can therefore be improved. This feature is described in detail below with reference to FIGS. 3 and 4 and is for an example of the upper arm as a representative.

FIG. 3 is a circuit diagram of the upper arm of the semiconductor module 10. In FIG. 3, an electrical connection configuration of four semiconductor switching elements 31a and four semiconductor elements 32a mounted on one substrate 20a is illustrated.

In the example illustrated in FIG. 3, each of the semiconductor switching elements 31a is a MOSFET. As illustrated in FIG. 3, in the upper arm, the control terminal 82 is electrically connected to the sources of the four semiconductor switching elements 31a via the electrode pattern 22a3 without passing the principal current path. Thus, the principal current path is not interposed in the current path for controlling driving of each of the semiconductor switching elements 31a. As a result, the current path for controlling driving of each of the semiconductor switching elements 31a is less likely to be affected by current variations in the relevant principal current path.

The path length of the principal current path differs according to the semiconductor switching elements 31a. Accordingly, the principal current paths each have parasitic inductances L differing according to the semiconductor switching elements 31a. As a result, when the principal current fluctuates, counter-electromotive force of a different magnitude is generated in the parasitic inductance L for each of the semiconductor switching elements 31a.

However, in the semiconductor module 10, as described above, the principal current path is not interposed in the current path for controlling driving of each of the semiconductor switching elements 31a. As a result, the current path for controlling driving of each of the semiconductor switching elements 31a is not affected by the counter-electromotive force. Flow and imbalance of currents among the gates of the four semiconductor switching elements 31a electrically connected in parallel are less likely to occur, so that oscillation due to repetition of charge and discharge can be prevented. With arrangement of the current paths for controlling driving of the semiconductor switching elements 31a to be close to one another among the four semiconductor switching elements 31a, a loop formed by these current paths can be reduced in the size. As a result, electromagnetic radiation noise from peripheral circuits is less likely to be interlinked and a risk of false turn-on and the like can accordingly be decreased. Additionally, due to the effects described above, there is an advantage in that the sources of the semiconductor switching elements 31a do not need to be connected by wires.

FIG. 4 is a circuit diagram of an upper arm of a semiconductor module 10X having a configuration in which an auxiliary control terminal 82X is connected to the principal current paths. The semiconductor module 10X is configured in substantially the same manner as the semiconductor module 10 except that the control terminal 82X is included instead of the control terminal 82.

In the semiconductor module 10X, in the upper arm, the control terminal 82X is electrically connected to the source of each of the four semiconductor switching elements 31a via the principal current path as illustrated in FIG. 4. Accordingly, in the current path for controlling driving of each of the semiconductor switching elements 31a, the parasitic inductance L of the relevant principal current path is interposed.

As a result, in the semiconductor module 10X, when counter-electromotive force is generated in the parasitic inductances L due to variations in the principal current, flows and imbalance of currents among the gates of the four semiconductor switching elements 31a electrically connected in parallel occur as indicated by broken line arrows in FIG. 4. The result increases a risk of false turn-on, damage to elements, and the like, in the semiconductor module 10X, due to oscillation caused by repetition of charge and discharge.

1-2. Details of electrode patterns and wires

FIG. 5 is a side view for explaining the semiconductor switching elements 31a and the semiconductor elements 32a on each of the substrates 20a for the upper arm. FIG. 6 is a plan view illustrating a configuration of each of the substrates 20a for the upper arm. For the sake of simplicity, illustrations of the wires 91a, 92a, 93a, 94a, and 95 are omitted in FIG. 5.

As illustrated in FIGS. 5 and 6, the electrode pattern 22a2, the electrode pattern 22a1, the electrode pattern 22a3, and the electrode pattern 22a4 are arrayed in this order in the X1 direction.

In the example illustrated in FIG. 6, each of the electrode pattern 22a3 and the electrode pattern 22a4 has an elongated shape extending in a direction along the Y-axis. Either ends of the electrode pattern 22a2, the electrode pattern 22a1, the electrode pattern 22a3, and the electrode pattern 22a4 in the direction along the Y-axis are aligned with one another. As a result, the lengths of the electrode pattern 22a2, the electrode pattern 22a1, the electrode pattern 22a3, and the electrode pattern 22a4 in the direction along the Y-axis are equal. One of the electrode pattern 22a2, the electrode pattern 22a1, the electrode pattern 22a3, and the electrode pattern 22a4 is provided in the entire region in a direction along the Y-axis.

The shape of each of the electrode pattern 22a1, the electrode pattern 22a2, the electrode pattern 22a3, and the electrode pattern 22a4 is not limited to that in the example illustrated in FIG. 6. For example, the lengths of the electrode pattern 22a2, the electrode pattern 22a1, the electrode pattern 22a3, and the electrode pattern 22a4 in the direction along the Y-axis may differ from one another.

Multiple semiconductor switching elements 31a and multiple semiconductor elements 32a are joined to the electrode pattern 22a1 with a conductive joining material, such as solder. In the example illustrated in FIG. 6, four semiconductor switching elements 31a are arrayed in the direction along the Y-axis and four semiconductor elements 32a are arrayed in the direction along the Y-axis at positions in the X1 direction with respect to the four semiconductor switching elements 31a.

Each of the semiconductor switching elements 31a has a first surface F1 and a second surface F2. The first surface F1 is a surface of the semiconductor switching element 31a to be joined to the electrode pattern 22a1. In the example illustrated in FIG. 5, the first surface F1 faces in the Z2 direction. Although not illustrated in the drawings, the input electrode as the drain electrode or the collector electrode is provided on the first surface F1 as described above. The second surface F2 is a surface of the semiconductor switching element 31a facing in the opposite direction to the first surface F1. A control electrode 311, a control line 312, and a main electrode 313 are provided on the second surface F2 as illustrated in FIG. 6.

The control electrode 311 is a gate electrode. A control voltage from the control circuit (not illustrated) is input to the control electrode 311. The control electrode 311 is constituted of, for example, a metal, such as aluminum. In the example illustrated in FIG. 6, the control electrode 311 is arranged at an end portion of the second surface F2 in the Y1 direction or the Y2 direction. The shape and the arrangement of the control electrode 311 are not limited to those of the example illustrated in FIG. 6. For example, the control electrode 311 may be arranged at an end portion of the second surface F2 in the X1 direction or the X2 direction.

The control electrode 311 is electrically connected to the electrode pattern 22a4 with the wire 93a. The wire 93a has one end to be joined to the electrode pattern 22a4 and the other end to be joined to the control electrode 311. In the example illustrated in FIG. 6, the wire 93a is constituted of one wire for each control electrode 311. The number of wires constituting the wire 93a for each control electrode 311 may be two or more.

The control line 312 is a line to be connected to the control electrode 311. For example, the control line 312 is a stacked body including a gate runner constituted of a semiconductor, such as polysilicon doped with impurities, and a gate metallic layer provided on the gate runner and constituted of a metal, such as aluminum. In the example illustrated in FIG. 6, the control line 312 extends in the Y1 direction or the Y2 direction from the control electrode 311. The shape of the control line 312 in plan view is determined according to the number of regions RE described below, the shapes thereof, or the like and is not limited to that in the example illustrated in FIG. 6. For example, the control line 312 may have a portion following an outer edge of the main electrode 313 in plan view.

The main electrode 313 is a source electrode or an emitter electrode and outputs a principal current when the semiconductor switching element 31a is in an on-state. The main electrode 313 is constituted of, for example, a metal such as aluminum, an aluminum alloy, titanium, or a titanium alloy. The main electrode 313 is divided by the control line 312 in plan view and has regions RE_1 and RE_2. Hereinafter, each of the region RE_1 and the region RE_2 is also referred to as “region RE.”

While a mode in which the main electrode 313 is divided into two regions RE is exemplified in FIG. 6, the main electrode 313 is not limited to this mode. For example, the main electrode 313 may have three or more regions RE. That is, the number of divisions of the main electrode 313 is not limited to two and may be three or more.

In the example illustrated in FIG. 6, the region RE_1 and the region RE_2 are arrayed in this order in the X1 direction. Each of the region RE_1 and the region RE_2 extends in the direction along the Y-axis. The shapes of the region RE_1 and the region RE_2 in plan view are the same. Each of the region RE_1 and the region RE_2 has a rectangular shape in plan view. The shapes of the region RE_1 and the region RE_2 in plan view are not limited to those in the example illustrated in FIG. 6. The shapes thereof in plan view may differ from each other. Each of the region RE_1 and the region RE_2 may extend in the direction along the X-axis.

Although not illustrated in the drawings, each of the semiconductor switching elements 31a includes multiple transistor parts corresponding to the regions RE and constituting a transistor, such as an IGBT or a power MOSFET. Each of the regions RE is electrically connected to a source region or an emitter region of the corresponding transistor part. The regions RE are electrically isolated from each other on the second surface F2 and output principal currents independently of each other. A gate of each of the transistor parts is electrically connected to the control line 312. Accordingly, the gates are electrically connected to the control electrode 311 via the control line 312. In each of the semiconductor switching elements 31a, a diode part, such as an FWD, may be provided with respect to each region RE in addition to the transistor part.

Each of the region RE_1 and the region RE_2 is electrically connected to the electrode pattern 22a2 with the wire 91a and is electrically connected to the electrode pattern 22a3 with the wire 92a.

The wire 91a has one end to be joined to the electrode pattern 22a2 and the other end to be joined to a region RE. In the example illustrated in FIG. 6, the wire 91a for each region RE comprises a pair of two wires. The number of wires comprising the wire 91a for each region RE may be one, three, or more.

The wire 92a has one end to be joined to the electrode pattern 22a3 and the other end to be joined to a region RE. In the example illustrated in FIG. 6, the wire 92a for each region RE comprises a pair of two wires. The number of wires comprising the wire 92a for each region RE may be one, three, or more.

An intermediate portion of the wire 92a is joined to a semiconductor element 32a by stitch bonding. The intermediate portion of the wire 92a is at any position between one end of the wire 92a and the other end thereof. As illustrated in FIG. 5, each of the semiconductor elements 32a has a third surface F3 and a fourth surface F4. The third surface F3 is a surface of each semiconductor element 32a to be joined to the electrode pattern 22a1. In the example illustrated in FIG. 5, the third surface F3 faces in the Z2 direction. As described above, an output electrode as a cathode electrode is provided on the third surface F3 although not illustrated in the drawings. The fourth surface F4 is a surface of each semiconductor element 32a facing in the opposite direction to the third surface F3. As described above, an input electrode as an anode electrode is provided on the fourth surface F4 and the intermediate portion of the wire 92a is joined thereto although not illustrated in the drawings.

The electrode patterns 22a1 of the two substrates 20a are electrically connected to each other via the main terminal 71 although illustrations thereof are omitted in FIG. 6. In FIG. 6, the region CTa to which the main terminal 71 is to be joined is hatched. In the example illustrated in FIG. 6, the region CTa is positioned in the center of the electrode pattern 22a1 in the direction along the Y-axis. The position of the region CTa is not limited to that in the example illustrated in FIG. 6 and may be a position deviated from the center of the electrode pattern 22a1 in the direction along the Y-axis.

The electrode patterns 22a3 of the two substrates 20a are electrically connected to each other via the control terminal 82 although illustrations thereof are omitted in FIG. 6. In FIG. 6, the region CTb to which the control terminal 82 is to be joined is hatched. In the example illustrated in FIG. 6, the region CTb is positioned in the center of the electrode pattern 22a3 in the direction along the Y-axis. The position of the region CTb is not limited to that in the example illustrated in FIG. 6, and it may be a position deviated from the center of the electrode pattern 22a3 in the direction along the Y-axis.

In the present embodiment, the electrode patterns 22a3 of the two substrates 20a are not only electrically connected to each other via the control terminal 82 but are also electrically connected to each other via the wire 94a being one example of the “fourth wire.”

The wire 94a has two ends, one of which is an end to be joined to the electrode pattern 22a3 of one substrate 20a out of the two substrates 20a, and the other of which is an end to be joined to the electrode pattern 22a3 of the other substrate 20a. In the example illustrated in FIG. 6, the wire 94a comprises one wire. The number of wires constituting the wire 94a may be two or more.

Furthermore, the electrode patterns 22a4 of the two substrates 20a are electrically connected to each other via the control terminal 81 although illustrations thereof are omitted in FIG. 6. In FIG. 6, the region CTc to which the control terminal 81 is to be joined is hatched. In the example illustrated in FIG. 6, the region CTc is positioned in the center of the electrode pattern 22a4 in the direction along the Y-axis. The position of the region CTc is not limited to that in the example illustrated in FIG. 6, and it may be a position deviated from the center of the electrode pattern 22a4 in the direction along the Y-axis.

The electrode pattern 22a2 of each of the substrates 20a is electrically connected to the electrode pattern 22b1 of a substrate 20b described later via the wires 95. The wire 95 has two ends, one of which is an end to be joined to the electrode pattern 22a2 of the substrate 20a, and the other of which is an end to be joined to the electrode pattern 22b1 of the substrate 20b. In the example illustrated in FIG. 6, the wire 95 is constituted of a plurality of wires. The number of wires comprising the wire 95 and arrangement thereof are not limited to those in the example illustrated in FIG. 6, and it may be freely selected.

FIG. 7 is a plan view illustrating a configuration of each of the substrates 20b for the lower arm. As illustrated in FIG. 7, the electrode pattern 22b2, the electrode pattern 22b1, the electrode pattern 22b3, and the electrode pattern 22b4 are arrayed in this order in the X2 direction.

In the example illustrated in FIG. 7, each of the electrode pattern 22b3 and the electrode pattern 22b4 has an elongated shape extending in the direction along the Y-axis. Either ends of the electrode pattern 22b1, the electrode pattern 22b3, and the electrode pattern 22b4 in the direction along the Y-axis are aligned with one another. As a result, the lengths of the electrode pattern 22b1, the electrode pattern 22b3, and the electrode pattern 22b4 in the direction along the Y-axis are equal. One of the electrode pattern 22b1, the electrode pattern 22b3, and the electrode pattern 22b4 is provided in the entire region in a direction along the Y-axis. The length of each of the electrode pattern 22b1, the electrode pattern 22b3, and the electrode pattern 22b4 in the direction along the Y-axis is greater than the length of the electrode pattern 22b2 in the direction along the Y-axis. The ends of the electrode pattern 22b1 and the electrode pattern 22b2 in the X1 direction are aligned with each other.

The shape of each of the electrode pattern 22b1, the electrode pattern 22b2, the electrode pattern 22b3, and the electrode pattern 22b4 is not limited to that in the example illustrated in FIG. 7. For example, the lengths of the electrode pattern 22b1, the electrode pattern 22b3, and the electrode pattern 22b4 in the direction along the Y-axis may differ from one another.

Multiple semiconductor switching elements 31b and multiple semiconductor elements 32b are joined to the electrode pattern 22b1 with a conductive joining material, such as solder. In the example illustrated in FIG. 7, four semiconductor switching elements 31b are arrayed in the direction along the Y-axis, and four semiconductor elements 32b are arrayed in the direction along the Y-axis at positions in the X2 direction with respect to the four semiconductor switching elements 31b.

Although not illustrated in the drawings, each of the semiconductor switching elements 31b has the first surface F1 and the second surface F2 similarly to the semiconductor switching elements 31a.

Each of the region RE_1 and the region RE_2 of each of the semiconductor switching elements 31b is electrically connected to the electrode pattern 22b2 with the wire 91b and is electrically connected to the electrode pattern 22b3 with the wire 92b.

The wire 91b has two ends, one of which is an end to be joined to the electrode pattern 22b2, and the other of which is an end to be joined to a region RE. Accordingly, the electrode pattern 22b2 and each region RE are electrically connected to each other with the wire 91b. In the example illustrated in FIG. 7, the wire 91b is constituted of two wires with respect to each region RE. The number of wires constituting the wire 91b with respect to each region RE may be one, three, or more.

The wire 92b has two ends, one of which is an end to be joined to the electrode pattern 22b3, and the other of which is an end to be joined to a region RE. By the wire 92b, the electrode pattern 22b3 and each region RE are electrically connected to each other with the wire 92b. In the example illustrated in FIG. 7, the wire 92b c for each region RE comprises a pair of two wires. The number of wires comprising the wire 92b for each region RE may be one, three, or more.

An intermediate portion of the wire 92b is joined to the semiconductor element 32b by stitch bonding. The intermediate portion of the wire 92b is at any position between one end of the wire 92b and the other thereof. Although not illustrated in the drawings, each of the semiconductor elements 32b has the third surface F3 and the fourth surface F4 similarly to the semiconductor elements 32a. The intermediate portion of the wire 92b is joined to the fourth surface F4 of a semiconductor element 32b.

The electrode patterns 22b1 of the two substrates 20b are electrically connected to each other via the main terminal 73 although illustrations thereof are omitted in FIG. 7. In FIG. 7, the region CTd to which the main terminal 73 is to be joined is hatched. In the example illustrated in FIG. 7, the region CTd is positioned in the center of the electrode pattern 22b1 in the direction along the Y-axis. The position of the region CTb is not limited to that in the example illustrated in FIG. 7 and may be a position deviated from the center of the electrode pattern 22b1 in the direction along the Y-axis.

The electrode patterns 22b2 of the two substrates 20b are electrically connected to each other via the main terminal 72 although illustrations thereof are omitted in FIG. 7. In FIG. 7, the region CTe to which the main terminal 72 is to be joined is hatched. In the example illustrated in FIG. 7, the region CTe is positioned in the center of the electrode pattern 22b1 in the direction along the Y-axis. The position of the region CTe is not limited to that in the example illustrated in FIG. 7, and it may be a position deviated from the center of the electrode pattern 22b2 in the direction along the Y-axis.

The electrode patterns 22b3 of the two substrates 20b are electrically connected to each other via the control terminal 84 although illustrations thereof are omitted in FIG. 7. In FIG. 7, the region CTf to which the control terminal 84 is to be joined is hatched. In the example illustrated in FIG. 7, the region CTf is positioned in the center of the electrode pattern 22b3 in the direction along the Y-axis. The position of the region CTf is not limited to that in the example illustrated in FIG. 7, and it may be a position deviated from the center of the electrode pattern 22b3 in the direction along the Y-axis.

In the present embodiment, the electrode patterns 22b3 of the two substrates 20b are not only electrically connected to each other via the control terminal 84 but are also electrically connected to each other via the wire 94b being one example of the “fourth wire.” The wire 94b has one end to be joined to the electrode pattern 22b3 of one substrate 20b out of the two substrates 20b, and the other end to be joined to the electrode pattern 22b3 of the other substrate 20b. In the example illustrated in FIG. 7, the wire 94b is constituted of one wire. The number of wires constituting the wire 94b may be two or more.

Furthermore, the electrode patterns 22b4 of the two substrates 20b are electrically connected to each other via the control terminal 83 although illustrations thereof are omitted in FIG. 7. In FIG. 7, the region CTg to which the control terminal 83 is to be joined is hatched. In the example illustrated in FIG. 7, the region CTg is positioned in the center of the electrode pattern 22b4 in the direction along the Y-axis. The position of the region CTg is not limited to that in the example illustrated in FIG. 7, and it may be a position deviated from the center of the electrode pattern 22b4 in the direction along the Y-axis.

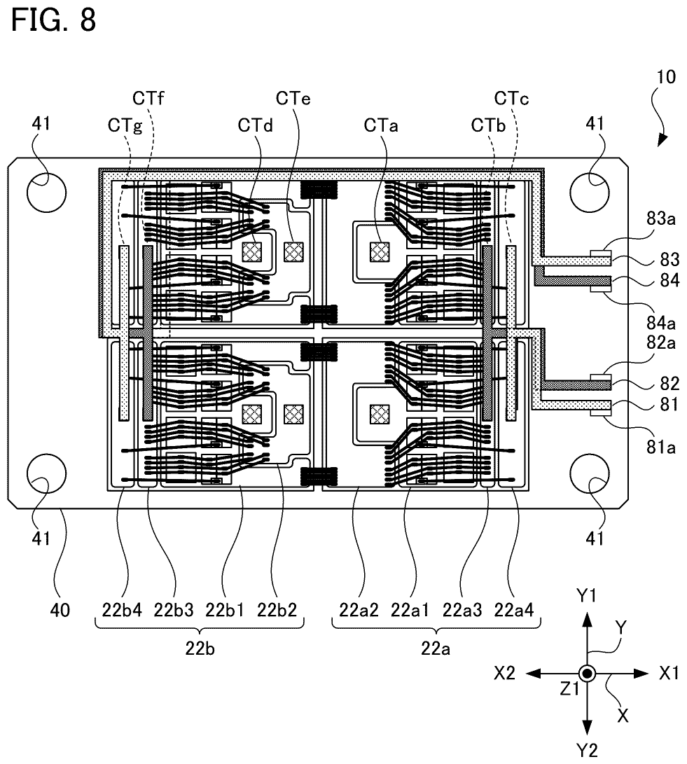

FIG. 8 is a plan view illustrating a configuration example of the control terminals 81, 82, 83, and 84. In FIG. 8, to facilitate understanding, the control terminals 81 and 83 and the control terminals 82 and 84 are illustrated with different grayscale densities.

As illustrated in FIG. 8, the control terminal 81 is joined to the region CTc of the electrode pattern 22a4 of each of the two substrates 20a. Similarly, the control terminal 82 is joined to the region CTb of the electrode pattern 22a3 of each of the two substrates 20a. The control terminal 83 is joined to the region CTg of the electrode pattern 22b4 of each of the two substrates 20b. The control terminal 84 is joined to the region CTf of the electrode pattern 22b3 of each of the two substrates 20b.

As described above, the semiconductor module 10 includes at least one substrate 20a and multiple semiconductor switching elements 31a in the upper arm. Similarly, the semiconductor module 10 includes at least one substrate 20b and multiple semiconductor switching elements 31b in the lower arm.

The at least one substrate 20a in the upper arm includes the electrode pattern 22a1 (an example of the “first electrode pattern”), the electrode pattern 22a2 (an example of the “second electrode pattern”), and the electrode pattern 22a3 (an example of the “third electrode pattern”). The electrode pattern 22a1 is positioned between the electrode pattern 22a2 and the electrode pattern 22a3 in plan view. Similarly, in the lower arm, the at least one substrate 20b includes the electrode pattern 22b1 (an example of the “first electrode pattern”), the electrode pattern 22b2 (an example of the “second electrode pattern”), and the electrode pattern 22b3 (an example of the “third electrode pattern”). The electrode pattern 22b1 is positioned between the electrode pattern 22b2 and the electrode pattern 22b3 in plan view.

Each of the semiconductor switching elements 31a in the upper arm includes the first surface F1 to be joined to the electrode pattern 22a1 and the second surface F2 facing in the opposite direction to the first surface F1. Similarly, each of the semiconductor switching elements 31b in the lower arm includes the first surface F1 to be joined to the electrode pattern 22b1 and the second surface F2 facing in the opposite direction to the first surface F1. The control electrode 311, the control line 312 to be connected to the control electrode 311, and the main electrode 313 having multiple regions RE divided by the control line 312 are provided on the second surface F2.

In addition, each of the regions RE in the upper arm is electrically connected to the electrode pattern 22a2 via the wire 91a (an example of the “first wire”) and is electrically connected to the electrode pattern 22a3 via the wire 92a (an example of the “second wire”). The electrode pattern 22a2 is a pattern for the principal current. The electrode pattern 22a3 is used as an auxiliary pattern for control. Similarly, each of the regions RE in the lower arm is electrically connected to the electrode pattern 22b2 via the wire 91b (an example of the “firs wire”) and is electrically connected to the electrode pattern 22b3 via the wire 92b (an example of the “second wire”). The electrode pattern 22b2 is a pattern for the principal current. The electrode pattern 22b3 is used as an auxiliary pattern for control.

In the above semiconductor module 10, the electrode patterns 22a3 and 22b3 that are electrically connected to the main electrode 313 via different paths from the principal current path are used as auxiliary patterns for control. As a result, deterioration of the switching characteristics due to variation of the parasitic inductance L, counter-electromotive force, and the like on the principal current path is decreased. Furthermore, each of the regions RE of the main electrode 313 is electrically connected to each of the electrode patterns 22a3 and 22b3 via the wires 92a and 92b, so that imbalance of the current in the main electrode 313 is decreased. As a result, switching characteristics are improved.

The semiconductor module 10 of the present embodiment further includes the control terminals 82 and 84 being examples of the “first control terminal.” The control terminal 82 is joined to the electrode patterns 22a3. Accordingly, as compared to a configuration in which each of the semiconductor switching elements 31a is electrically connected to the control terminal 82 via a pattern on the substrate 20a other than the electrode pattern 22a3, an advantage is that the current of the main electrode 313 can be more easily equalized among the semiconductor switching elements 31a. Such an advantage contributes to improvement of the switching characteristics. Another advantage is that wiring for the control terminal 82 can be simplified in the configuration in which the control terminal 82 is joined to the electrode patterns 22a3. Since the control terminal 84 is joined to the electrode patterns 22b3, substantially the same advantages as those in the configuration in which the control terminal 82 is joined to the electrode patterns 22a3 are obtained. Use of the control terminals 82 and 84 reduces the area of wiring on the substrates 20a and 20b. As a result, an area necessary to mount semiconductor chips and the like on the substrates 20a and 20b can be easily allocated.

As described above, each of the electrode patterns 22a3 has an elongated shape. The control terminal 82 is joined to a place closer to the center of each of the electrode patterns 22a3 than ends thereof in the length direction. That is, the distance between (i) the joining place between an electrode pattern 22a3 and the control terminal 82, and (ii) the center of the electrode pattern 22a3 in the length direction is less than the distance between (i) the joining place between the electrode patten 22a3 and the control terminal 82, and (ii) each of the ends of the electrode pattern 22a3 in the length direction. Accordingly, there is an advantage in that imbalance of the current in each of the electrode patterns 22a3 is easily decreased. Such an advantage contributes to improvement of the switching characteristics. Similarly, since each of the electrode patterns 22b3 has an elongated shape and the control terminal 84 is joined to a place closer to the center of an electrode pattern 22b3 than ends thereof in the length direction, imbalance of the current in the electrode pattern 22b3 can also be decreased.

As described above, the semiconductor module 10 further includes the control terminals 81 and 83 (examples of the “second control terminal”). The at least one substrate 20a further includes the electrode pattern 22a4 (an example of the “fourth electrode pattern”). The electrode pattern 22a4 is electrically connected to the control electrode 311 via the wire 93a (an example of the “third wire”). The control terminal 81 is joined to the electrode pattern 22a4. The electrode pattern 22a3 is positioned between the electrode pattern 22a1 and the electrode pattern 22a4 in plan view. Accordingly, each of the electrode pattern 22a3 and the electrode pattern 22a4 can be spaced from the electrode pattern 22a2 for the principal current. As a result, each of the electrode pattern 22a3 and the electrode pattern 22a4 can be made less subject to electric reactor influences due to variations in the principal current. Imbalance of the current can be decreased and false turn-on can be prevented. With this positioning of the electrode pattern 22a3 to be closer to the electrode pattern 22a1 than the electrode pattern 22a4 is, the wires 93a can be easily formed and are therefore easily mounted even when the number of wires constituting the wire 92a is large. Furthermore, the length of the wire 92a can be shortened as compared to a configuration in which the electrode pattern 22a4 is positioned between the electrode pattern 22a3 and the electrode pattern 22a1 in plan view. As a result, imbalance of the current among the main electrodes 313 of the semiconductor switching elements 31a can be decreased.

Similarly, the at least one substrate 20b further includes the electrode pattern 22b4 (an example of the “fourth electrode pattern”). The electrode pattern 22b4 is electrically connected to the control electrode 311 via the wire 93b (an example of the “third wire”). The control terminal 83 is joined to the electrode pattern 22b4. The electrode pattern 22b3 is positioned between the electrode pattern 22b1 and the electrode pattern 22b4 in plan view. Accordingly, each of the electrode pattern 22b3 and the electrode pattern 22b4 can be spaced from the electrode pattern 22b2 for the principal current. As a result, each of the electrode pattern 22b3 and the electrode pattern 22b4 can be made less subject to electric reactor influences due to variations in the principal current. Imbalance of the current can be decreased and false turn-on can be prevented. With this positioning of the electrode pattern 22b3 to be closer to the electrode pattern 22b1 than the electrode pattern 22b4 is, the wires 93b can be easily formed and are therefore easily mounted even when the number of wires constituting the wire 92b is large. Furthermore, the length of the wire 92b can be shortened as compared to a configuration in which the electrode pattern 22b4 is positioned between the electrode pattern 22b3 and the electrode pattern 22b1 in plan view. As a result, imbalance of the current among the main electrodes 313 of the semiconductor switching elements 31b can be decreased.

As described above, the at least one substrate 20a includes multiple substrates 20a each having the electrode pattern 22a1, the electrode pattern 22a2, and the electrode pattern 22a3. The control terminal 82 is joined to the electrode pattern 22a3 of each of the substrates 20a. As a result, imbalance of the current among the electrode patterns 22a3 of the substrates 20a can be decreased.

Similarly, the at least one substrate 20b includes multiple substrates 20b each having the electrode pattern 22b1, the electrode pattern 22b2, and the electrode pattern 22b3. The control terminal 84 is joined to the electrode pattern 22b3 of each of the substrates 20b. As a result, imbalance of the current among the electrode patterns 22b3 of the substrates 20b can be decreased.

As described above, the semiconductor module 10 further includes the wires 94a and 94b (examples of the “fourth wire”). The wire 94a electrically connects the electrode patterns 22a3 of the substrates 20a to each other. As a result, imbalance of the current among the electrode patterns 22a3 of the substrates 20a can be decreased. Similarly, the wire 94b electrically connects the electrode patterns 22b3 of the substrates 20b to each other. As a result, imbalance of the current among the electrode patterns 22b3 of the substrates 20b can be decreased.

The foregoing semiconductor switching elements 31a are electrically connected in parallel. Similarly, the semiconductor switching elements 31b are electrically connected in parallel. This housing provides the above remarkable effects of decreasing reduction of the switching characteristics due to variation of the parasitic inductance L, the counter-electromotive force, and the like on the principal current path.

The foregoing wire 92a comprises multiple wires for each of the regions RE. As a result, imbalance of the current in the main electrode 313 of each of the semiconductor switching elements 31a can be appropriately decreased. Similarly, the wire 92b comprises multiple wires for each of the regions RE. As a result, imbalance of the current in the main electrode 313 of each of the semiconductor switching elements 31b can be appropriately decreased.

The foregoing semiconductor module 10 further includes a plurality of semiconductor elements 32a in the upper arm. Each of the semiconductor elements 32a has the third surface F3 to be joined to the electrode pattern 22al, and the fourth surface F4 facing in the opposite direction to the third surface F3. An intermediate portion of the wire 92a is joined to the fourth surface F4. Accordingly, even in a configuration in which the semiconductor elements 32a being different members from the semiconductor switching elements 31a are included, imbalance of the current in the main electrode 313 of each of the semiconductor switching elements 31a can be appropriately decreased.

Similarly, the semiconductor module 10 further includes multiple semiconductor elements 32b in the lower arm. Each of the semiconductor elements 32b has the third surface F3 to be joined to the electrode pattern 22b1 and the surface F4 facing in the opposite direction to the third surface F3. An intermediate portion of the wire 92b is joined to the fourth surface F4. As a result, even in a configuration in which the semiconductor elements 32b being different members from the semiconductor switching elements 31b are included, imbalance of the current in the main electrode 313 of each of the semiconductor switching elements 31b can be appropriately decreased.

### 2. Modifications

The present disclosure is not limited to the foregoing embodiment, and a variety of modifications is derived therefrom. The embodiment and modifications may be combined with one another as appropriate.

### 2-1. First Modification

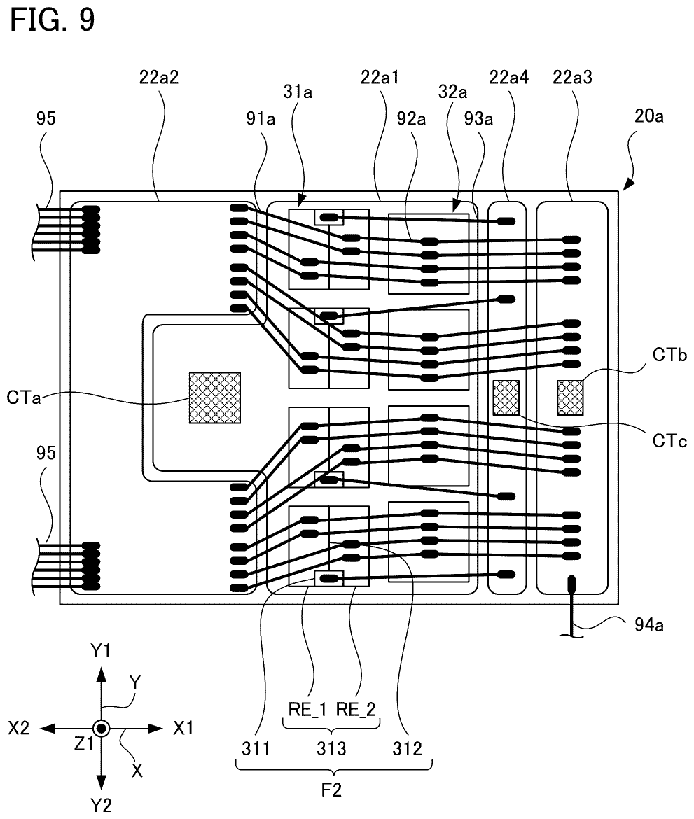

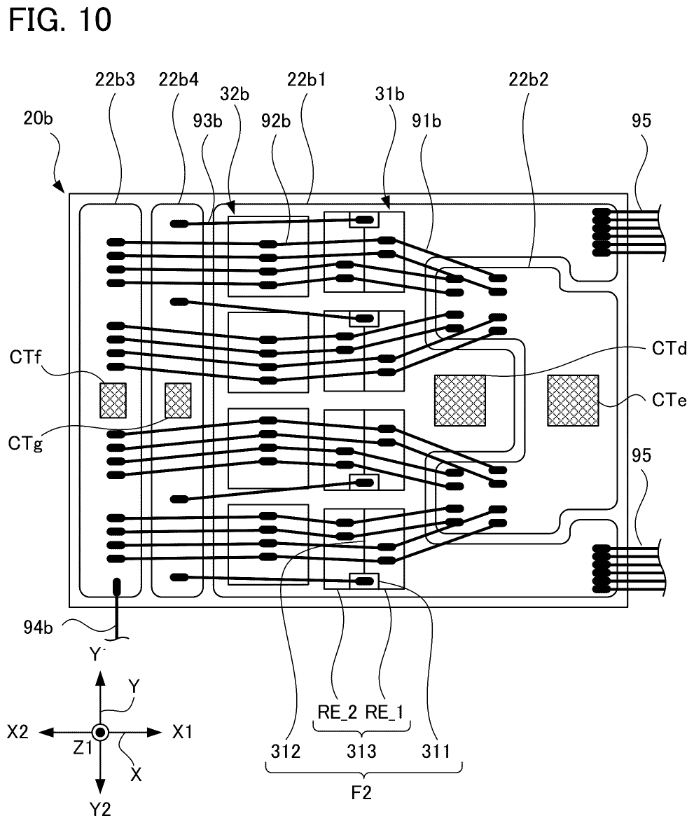

FIG. 9 is a plan view illustrating a configuration of a substrate 20a for the upper arm according to a first modification. FIG. 10 is a plan view illustrating a configuration of the substrate 20b for the lower arm according to the first modification.

The first modification is substantially the same as the foregoing embodiment. However, arrangement of the electrode pattern 22a3 and the electrode pattern 22a4 is switched and that arrangement of the electrode pattern 22b3 and the electrode pattern 22b4 is switched.

According to the first modification, the switching characteristics can be improved similarly to the embodiment described above. In the first modification, the electrode pattern 22a4 (an example of the “fourth electrode pattern”) is positioned between the electrode pattern 22a1 (an example of the “first electrode pattern”) and the electrode pattern 22a3 (an example of the “third electrode pattern”) in plan view. Accordingly, each of the electrode pattern 22a3 and the electrode pattern 22a4 can be spaced apart from the electrode pattern 22a2 for the principal current. As a result, each of the electrode pattern 22a3 and the electrode pattern 22a4 can be made less subject to electric reactor influences due to variation in the principal current. Imbalance of the current can be decreased, and false turn-on can be prevented. With this positioning of the electrode pattern 22a3 to be spaced apart from the electrode pattern 22a1 than the electrode patten 22a4 is, the wires 92a can be easily joined to the electrode pattern 22a3 even when the diameter of each of wires constituting the wire 92a is greater than 400 micrometers (μm). In addition, since a region between the electrode pattern 22a1 and the electrode pattern 22a3 is effectively used by the electrode pattern 22a4, the substrates 20a can be downsized.

Similarly, the electrode pattern 22b4 (an example of the “fourth electrode pattern”) is positioned between the electrode pattern 22b1 (an example of the “first electrode pattern”) and the electrode pattern 22b3 (an example of the “third electrode pattern”) in plan view. Accordingly, each of the electrode pattern 22b3 and the electrode pattern 22b4 can be spaced apart from the electrode pattern 22b2 for the principal current. As a result, each of the electrode pattern 22b3 and the electrode pattern 22b4 can be made less subject to electric reactor influences due to variation in the principal current. Imbalance of the current can be decreased, and false turn-on can be prevented. With this positioning of the electrode pattern 22b3 to be distanced from the electrode pattern 22b1 than the electrode patten 22b4 is, the wires 92b can be easily joined to the electrode pattern 22b3 even when the diameter of each of wires constituting the wire 92b is greater than 400 μm. In addition, since a region between the electrode pattern 22b1 and the electrode pattern 22b3 is effectively used by the electrode pattern 22b4, the size of the substrates 20b can be decreased.

### 2-2. Second Modification

In the modes described above, the number of the semiconductor switching elements 31a or the semiconductor elements 32a mounted on each of the substrates 20a is four. However, this number may be not less than one and not greater than three, or it may be equal to or greater than five. Similarly, while the number of the semiconductor switching elements 31b or the semiconductor elements 32b mounted on each of the substrates 20b is four, this number may be not less than one and not greater than three, or it may be equal to or greater than five.

### 2-3. Third Modification

In the foregoing embodiment, the number of the substrates 20a or the substrates 20b is two. However, this number may be one, or it may be three or more. The substrate 20a and the substrate 20b may be one unit. While the configurations of the substrates 20a and the substrates 20b are different from each other in the embodiment, the configurations are not limited thereto and the configurations of the substrates 20a and the substrates 20b may be the same.

### 2-4. Fourth Modification

In the foregoing embodiment, a configuration is described in which the base 40 is included separately from the radiating layers 23a and 23b of the substrates 20a and 20b. However, the configuration of the base 40 is not limited thereto. For example, the base 40 may act as the radiating layers 23a and 23b. In this housing, the base 40 is a part of the substrates 20a and 20b.

### DESCRIPTION OF REFERENCE SIGNS

10 . . . semiconductor module, 10X . . . semiconductor module, 20a . . . substrate, 20b . . . substrate, 21a . . . insulating plate, 21b . . . insulating plate, 22a . . . wiring layer, 22al . . . electrode pattern (first electrode pattern), 22a2 . . . electrode pattern (second electrode pattern), 22a3 . . . electrode pattern (third electrode pattern), 22a4 . . . electrode pattern (fourth electrode pattern), 22b . . . wiring layer, 22b1 . . . electrode pattern (first electrode pattern), 22b2 . . . electrode pattern (second electrode pattern), 22b3 . . . electrode pattern (third electrode pattern), 22b4 . . . electrode pattern (fourth electrode pattern), 23a . . . radiating layer, 23b . . . radiating layer, 31a . . . semiconductor switching element, 31b . . . semiconductor switching element, 32a . . . semiconductor element, 32b . . . semiconductor element, 40 . . . base, 41 . . . attachment hole, 50 . . . housing, 60 . . . lid, 71 . . . main terminal, 72 . . . main terminal, 73 . . . main terminal, 81 . . . control terminal, 81a . . . terminal part, 82 . . . control terminal, 82X . . . control terminal, 82a . . . terminal part, 83 . . . control terminal, 83a . . . terminal part, 84 . . . control terminal, 84a . . . terminal part, 91a . . . wire (first wire), 91b . . . wire (first wire), 92a . . . wire (second wire), 92b . . . wire (second wire), 93a . . . wire (third wire), 93b . . . wire (third wire), 94a . . . wire (fourth wire), 94b . . . wire (fourth wire), 95 . . . wire, 311 . . . control electrode, 312 . . . control line, 313 . . . main electrode, CTa . . . region, CTb . . . region, CTc . . . region, CTd . . . region, CTe . . . region, CTf . . . region, CTg . . . region, F1 . . . first surface, F2 . . . second surface, F3 . . . third surface, F4 . . . fourth surface, L . . . parasitic inductance, RE . . . region, RE_1 . . . region, RE_2 . . . region.

What is claimed is:

1. A semiconductor module comprising:
at least one substrate including a first electrode pattern, a second electrode pattern, and a third electrode pattern, the first electrode pattern being positioned between the second electrode pattern and the third electrode pattern in plan view; and
a plurality of semiconductor switching elements that each have a first surface to be joined to the first electrode pattern, and a second surface facing in an opposite direction to the first surface, wherein:
on the second surface, a control electrode, a control line to be connected to the control electrode, and a main electrode including a plurality of regions divided by the control line are provided,
each of the regions is electrically connected to the second electrode pattern via a first wire, and is electrically connected to the third electrode pattern via a second wire,
the second electrode pattern is a pattern for a principal current, and
the third electrode pattern is used as an auxiliary pattern for control.

2. The semiconductor module according to claim 1, further comprising a first control terminal to be joined to the third electrode pattern.

3. The semiconductor module according to claim 2, wherein:
the third electrode pattern has an elongated shape, and
a distance between (i) a joining place between the third electrode pattern and the first control terminal, and (ii) a center of the third electrode pattern in a length direction thereof is less than a distance between (i) the joining place between the third electrode pattern and the first control terminal, and (ii) each of ends of the third electrode pattern in the length direction.

4. The semiconductor module according to claim 2, further comprising a second control terminal, wherein:
the at least one substrate further includes a fourth electrode pattern to be electrically connected to the control electrode via a third wire,
the second control terminal is joined to the fourth electrode pattern, and
the third electrode pattern is positioned between the first electrode pattern and the fourth electrode pattern in plan view.

5. The semiconductor module according to claim 2, further comprising a second control terminal, wherein:
the at least one substrate further includes a fourth electrode pattern to be electrically connected to the control electrode via a third wire,
the second control terminal is joined to the fourth electrode pattern, and
the fourth electrode pattern is positioned between the first electrode pattern and the third electrode pattern in plan view.

6. The semiconductor module according to claim 2, wherein:
the at least one substrate comprises a plurality of substrates each having the first electrode pattern, the second electrode pattern, and the third electrode pattern, and
the first control terminal is joined to the third electrode pattern of each of the substrates.

7. The semiconductor module according to claim 6, further comprising a fourth wire that is electrically connected to the third electrode pattern of each of the plurality of substrates.

8. The semiconductor module according to claim 1, wherein the semiconductor switching elements are electrically connected in parallel.

9. The semiconductor module according to claim 1, wherein the second wire for each of the regions comprises a plurality of wires.

10. The semiconductor module according to claim 1, further comprising a plurality of semiconductor elements that each have:
a third surface to be joined to the first electrode pattern; and
a fourth surface facing in an opposite direction to the third surface,
wherein an intermediate portion of the second wire is joined to the fourth surface.
